(19) United States
(12) Patent Application Publication
(10) Pub. No.: US 2005/0057309 A1
(43) Pub. Date: Mar. 17, 2005

(54) Transistor amplifier

(75) Inventor: Giuseppe Gramegna, Catania (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics S.r.I., Agrate Brianza (IT)

(21) Appl. No.: 10/942,617

(22) Filed: Sep. 16, 2004

(30) Foreign Application Priority Data
Sep. 16, 2003 (EP) 03425600.8

(51) Int. Cl. H03F 1/14

(52) U.S. Cl. 330/292

(57) ABSTRACT

An amplifier includes at least a first transistor which has a first input signal at a first input terminal and has a first output terminal at which a first output amplified signal is present. The first transistor comprises a first parasitic capacitive element which is arranged between the first input and output terminals and through which a first current flows. The stagecomprises a device having a second output terminal with an output signal having a value equal to but of different sign from the first output signal and it comprises at least one element which is arranged between the first input terminal of the first transistor and the second output terminal of the device and which is passed through by a second current having a value equal to but of different sign from the first current.

### BACKGROUND OF THE INVENTION

1. Field of the Invention

The present invention relates to a transistor amplifier.

2. Description of the Related Art

The actual amplifiers are generally composed by MOS or bipolar transistors in the respective common source and common emitter configurations. In such a way, in fact, said transistors amplify the input signal present at the gate terminal or at the base terminal.

However said transistors are affected by parasitic capacitances that change the frequency response performances as the capacitance Cgd arranged between the drain and gate terminals of the MOS transistor and the capacitance Cμ arranged between the collector and base terminal of the bipolar transistor. Said capacitances, even if they have a low value, because of the Miller effect can bring into a high distortion of the output signal of the respective transistor.

Low noise amplifiers (LNA) are presently produced which must satisfy the requirements of a high gain, of a low noise and of a high linearity; in addition, in the case of use in mobile appliances, for example notebooks, said amplifiers must satisfy the requirement of a low consumption.

A LNA amplifier is disclosed in the U.S. Pat. No. 5,721,500 and is shown in FIG. 1. The amplifier comprises two transconductance amplification stages 10 and 20 which are connected in series with each other. The two stages function in a similar manner and have similar components. The first stage 10 has a transconductance gain Gm given by Gm1+Gm2 where Gm1 and Gm2 are the transconductance gains of the respective transistors M1 and M2. The drain current of the transistor M1 is re-used in the transistor M2, the transconductance Gm increases without increasing the current consumption. The transistors M3-M7 make a bias current flow in the transistors M1 and M2 and the value of said bias current is fixed by means of the current reference Iref and by means of the current mirror M8-M2. There is even a low-pass filter that is composed by a resistance Rx and a capacitor Cx. The elements Ns and NI bring the value of the resistance at the input and output terminals to 50 Ω for inputting and outputting a radio frequency signal. The transistors M1 and M2 have the same bias voltage and a bias voltage Vb is at the gate terminals of the transistors M5. The output voltage V1 of the first stage 10 is in input to the second stage 20; the output voltage V2 of the second stage is the output voltage of the amplifier.

The circuit in FIG. 1 has the drawback of a frequency band reduction given by the Miller effect on the capacitance Cgd of the transistor M1. A solution for solving the aforementioned drawback consists of introducing a cascode stage for reducing the Miller effect; this causes however the application of a higher supply voltage.

### BRIEF SUMMARY OF THE INVENTION

One embodiment of the present invention provides a transistor amplifier that solves the problem of the frequency band reduction without applying a higher supply voltage.

The amplifier includes an amplifier stagehaving a first transistor which has a first input signal at a first input terminal and has a first output terminal at which a first output amplified signal is present, said first transistor comprising a first parasitic capacitive element which is arranged between the first input and output terminals and through which a first current flows. The stage further includes a device having a second output terminal with an output signal having a value equal to but of different sign from the first output signal. The stage also includes an element which is arranged between said first input terminal of the first transistor and said second output terminal of the device and which is passed through by a second current having a value equal to but of different sign from said first current.

### BRIEF DESCRIPTION OF THE SEVERAL VIEWS OF THE DRAWINGS

The features and the advantages of the present invention will be made evident by the following detailed description of embodiments thereof, shown as not limiting examples in the annexed drawings, wherein:

FIG. 1 is a scheme of a LNA amplifier according to prior art;

FIG. 2 shows a circuit scheme of an amplifier according to present invention;

FIG. 3 shows a circuit scheme of the amplifier according to a first embodiment of the present invention;

FIG. 4A shows a circuit scheme of the amplifier according to a second embodiment of the present invention;

FIG. 4B shows a circuit scheme of an amplifier according to a third embodiment of the present invention; and

FIG. 5 shows a circuit implementation of the amplifier in FIG. 4.

### DETAILED DESCRIPTION OF THE INVENTION

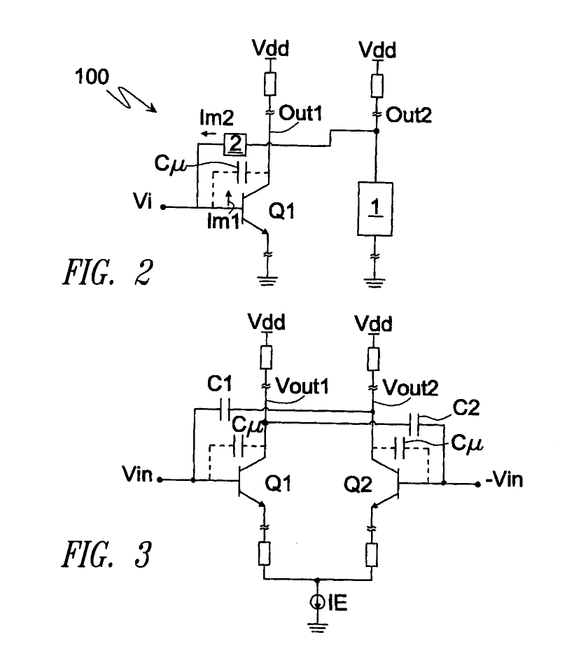

Referring to FIG. 2 is shown a scheme of the amplifier according to one embodiment the present invention. The amplifier in FIG. 2 comprises at least one amplifier stage 100 including a transistor Q1 that has an input signal Vi at a drivable terminal and an output terminal Out1 where an amplified output signal Vout1 is produced. The transistor Q1 comprises a parasitic capacitive element arranged between the input terminal and output terminal Out1; said parasitic capacitive element, because the transistor Q1 is schematized in FIG. 2 as a bipolar transistor, is constituted by the capacitance Cμ while if said transistor Q1 were schematized as a MOS transistor, the parasitic capacitive element would be the capacitance Cgd. A first current signal Im1 flows through the capacitance Cμ.

The amplifier stage 100 comprises a device 1, preferably an amplifier device, which has a second output terminal Out2 with an output signal Vout2 having a value equal to but of different sign from the first output signal Vout1.

The amplifier stage 100 comprises an element 2 arranged between the input terminal Vi of the transistor Q1 and the output terminal Out2 of the amplifier device 1; said element 2 is gone through by a current Im2 having a value substantially equal to but of different sign with respect to the current Im1. A supply voltage Vdd provides to supply the transistor Q1 and the device 1.

Without the element 2 all the capacitance seen from the input of the bipolar transistor Q2 for the Miller effect is given by Cπ+(G−1)*Cμ where Cπ is the capacitance between the base and emitter terminals and (G−1)*Cμ is the capacitive contribution given by the Miller effect where Cμ is the capacitance between the collector and base terminals and G is the voltage gain of the transistor Q1 wherein Vout1=−G*Vi. Therefore Cμ is gone through by a current Im1=s*Cμ*(G−1)*Vi. Canceling that current will eliminate the Miller effect.

With the presence of the element 2, by regarding that

Vout2=−Vout1=G*Vi and by supposing that the element 2 is a capacitance C1, the current that goes through C1 is Im2=s*(1−G)*C1*Vi. If C1 is substantially equal to Cμ it occurs that Im2=s*(1−G)*Cμ*Vi and the sum of the two currents Im1+Im2=2*s*Cμ*Vi so that the Miller effect is eliminated because the capacitive component (1−G)*Cμ is not seen any more from the input of the transistor Q1.

In FIG. 3 a circuit scheme of the amplifier in FIG. 2 according to a first embodiment of the present invention is shown. The device 1 of the amplifier stage 100 in FIG. 2 is formed as a bipolar transistor Q2 that forms with the transistor Q1 a differential pair having respective input voltages Vin and −Vin at the base terminals of the transistors Q1 and Q2. The differential pair Q1-Q2 is biased by means of a current generator IE coupled with the emitter terminals and is supplied by means of a supply voltage Vdd coupled with the collector terminals. Since the device 1 is implemented by the bipolar transistor Q2 even in said transistor Q2 the Miller effect occurs and therefore the Miller effect can be eliminated by inserting another element 2, indicated by a capacitance C2 in FIG. 3. If the sizes of the transistors Q1 and Q2 are equal, and therefore the parasitic capacitances Cμ of the two transistor are equal, the capacitance C2 must have a value equal to the capacitances C1 and Cμ for eliminating the Miller effect in the aforementioned way for the amplifier in FIG. 2.

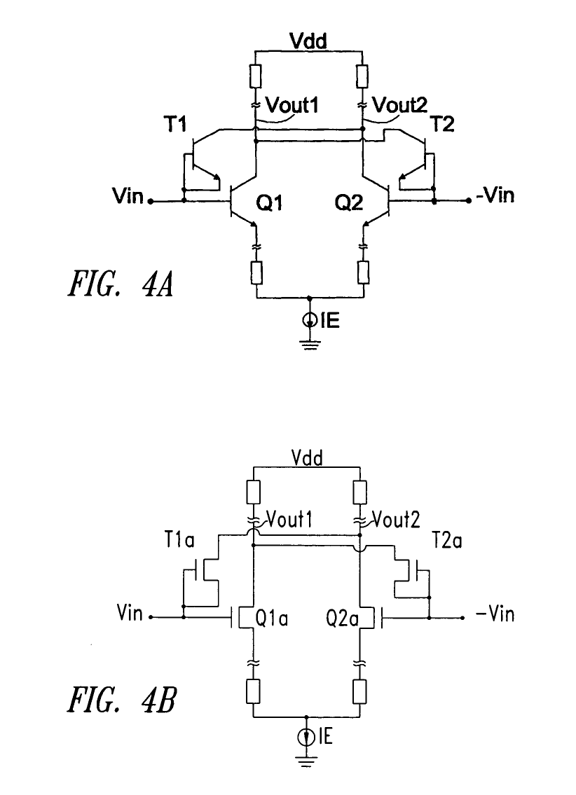

In FIG. 4A a circuit scheme of the amplifier in FIG. 2 according to a second embodiment of the present invention is shown. Said circuit scheme of the second embodiment is similar to that of the first embodiment in FIG. 3 except for the presence of an element 2 of different type with respect to that shown in FIG. 3. The element 2 is constituted by a bipolar transistor and, more specifically, two bipolar transistors T1 and T2 of equal size are arranged between the respective input terminals Vin, −Vin and the respective output terminals Vout2, Vout1. The transistors T1 and T2 are in diode connection and specifically they have the base terminal in common with the emitter terminal and connected respectively with the input terminals Vin and −Vin while they have the collector terminals connected respectively with the output terminals Vout2 and Vout1. The transistor T1 and T2 have entire capacitances Ct1 and Ct2 between the respective emitter and collector terminals which are substantially equal to the capacitances Cμ of the transistors Q1 and Q2. In such a way the Miller effect on the capacitances Cμ of the transistors Q1 and Q2 may be eliminated in the already above mentioned way.

A circuit of an amplifier according to a third embodiment of the invention is shown in FIG. 4B. The circuit of FIG. 4B is very similar to that of FIG. 4A except that MOS transistors are used instead of bipolar transistors. In particular, the amplifier of FIG. 4B includes a differential pair of first and second MOS transistors Q1a and Q2a having respective gate terminals coupled to the first and second input terminals Vin, −Vin. In addition, third and fourth MOS transistors T1a and T2a of equal size are arranged between the respective input terminals Vin, −Vin and the respective output terminals Vout2, Vout1. The transistors T1a and T2a are in diode connection and have respective gate terminals in common with respective source terminals, and respective collector terminals connected respectively with the output terminals Vout2 and Vout1. The transistor T1a and T2a have entire capacitances Ct1a and Ct2a between the respective source and drain terminals which are substantially equal to the capacitances Cμa of the transistors Q1a and Q2a. In such a way the Miller effect on the capacitances Cμa of the transistors Q1a and Q2a may be eliminated in the already above mentioned way.

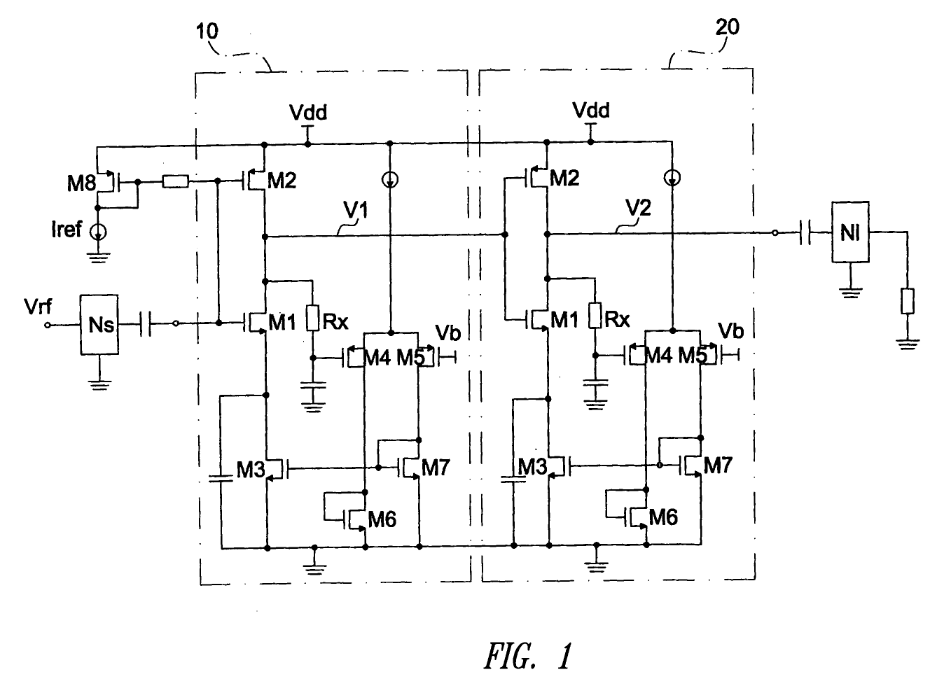

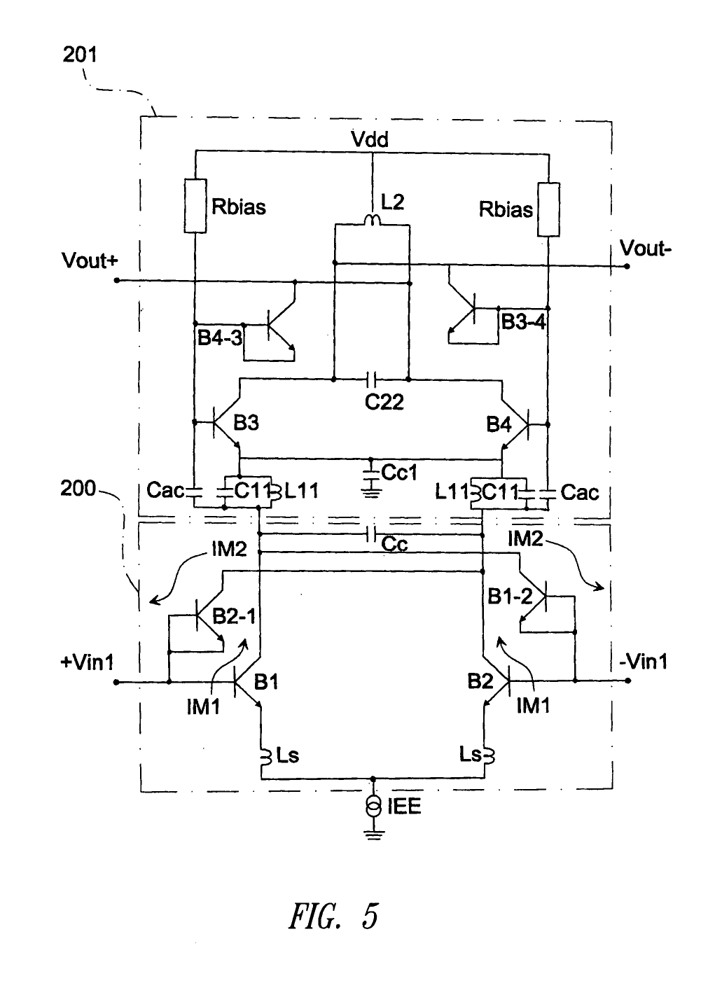

In FIG. 5 a circuit implementation of a two stage LNA amplifier according to the second embodiment of the present invention is shown. The amplifier in FIG. 1 is formed by a first stage 200 and by a second stage 201. The first stage 200 comprises a differential pair of bipolar transistors B1, B2 having respective emitter terminals connected respectively with inductances Ls connected in common to each other and connected with a current generator IEE connected to ground. The voltages Vin1 and −Vin1 are applied at the base terminals of the transistors B1 and B2 and the collector terminals are coupled to each other by means of a capacitance Cc. The output voltages at the collectors of the transistors B1 and B2 given respectively by G1*Vin1 and −G1*Vin1, where G1 is the gain of the stage 200.

The stage 201 is coupled in alternated current with the stage 200 by means of two capacitances Cac and it uses the same direct current. The stage 201 comprises a second differential pair of transistors B3 and B4 and the two capacitances Cac are connected respectively between the collector terminals of the transistors B1 and B2 and the base terminals of the transistors B3 and B4. The block constituted by the inductance L11 parallel to a capacitance C11 is connected between each collector terminal of the transistors B1 and B2 and each emitter terminal of the transistors B3 and B4. The emitter terminals of the transistors B3 and B4 are in common with each other and are coupled to ground by means of a capacitance Cc1, the collector terminals are coupled with each other by means of a block given by the inductance L22 parallel to a capacitance C22 and the base terminals are coupled with the supply voltage Vdd by means of two resistances Rbias.

By supposing that the Miller effect on the capacitances between the base and collector terminal is null, it occurs that the input resistance at the operating frequency fo is given by Rin(fo)=2 π*ft*Ls where ft is the cut-off frequency of the transistors B1 and B2. The input radio frequency match is obtained at the resonance frequency by making Rin(fo)=50 Ω. In such a condition the gain G(fo)=Vout/Vin where Vout is the output voltage in module at the collectors of the transistors B3 and B4 (the output voltages are Vout+ and Vout− respectively for the transistors B3 and B4) is given by:

$$G ( fo ) = ( ft / fo ) * ( \frac{1}{2 Rin ( fo )} ) * G2 * {( 2 π fo )}^{2} * ( L11 * Q11 ) * ( L2 * Q2 )$$

where L11 and L2 are the load inductances, Q11 and Q12 are their quality factors and G2 is the transconductance gain of the transistor B3 or B4.

By considering even the Miller effect on the capacitances between the base and collector terminals of the transistors B1-B4 we will obtain a higher value of the input resistance Rin(fo) and a worsening of the frequency response of the amplifier that has a reduced band, that is a lower cut-off frequency ft; for this reason it is desirable to cancel the Miller effect.

This can be obtained by placing the bipolar transistors B2-1, B1-2, B3-4, B4-3 respectively between the base terminals of the transistors B1-B4 and the collector terminals of the transistors B2, B1, B4, B3. The transistors B2-1, B1-2, B3-4, B4-3 are in diode connection and have the emitter terminals in common with the base terminals.

Since between the collector and base terminals there is a voltage difference given by (G1−1)Vin1, a current Im1=s*Cμ*(G1−1)*Vin1 will flow through the capacitance Cμ of the transistor B1. The addition of the transistor B2-1, which has a total capacitance between the emitter and collector terminals equal to the capacitance Cμ of the transistor B1 and wherein the voltage difference between the collector and base terminals has a value equal to but opposite from that of the transistor B1, allows the injection of a current IM2=−IM1 at the base terminal of the transistor B1; also it results that IM1−1M2=2*s*Cμ*Vin so the Miller effect on the capacitance Cμ of the transistor B1 has been cancelled and a total capacitance given by Cπ+2 Cμ is seen from the input. The transistors B1-2, B3-4 and B4-3 have the same function of the transistor B2-1 that is to cancel the Miller effect on the capacitances Cμ of the respective transistors B2, B4 and B3 in the same way already described for the transistor B1.

Amplifiers with more than two stages wherein each or at least one stage is formed according to present invention can be provided.

An additional advantage of said circuit solution for canceling the Miller effect consist of increasing the insulation between the input and the output of the amplifier as compared to the known amplifiers; this makes easier the matching at radio frequency of the input and of the output because the input and output networks can be optimized separately.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. An amplifier comprising an amplifier stage including:
a first transistor which has a first input signal at a first input terminal and has a first output terminal at which a first output amplified signal is present, said first transistor comprising a first parasitic capacitive element arranged between the first input and output terminals and through which a first current flows;
a device having a second output terminal with an output signal having a value equal to but of different sign from the first output signal; and
an element arranged between said first input terminal of the first transistor and said second output terminal of the device and which is passed through by a second current having a value equal to but of a different sign from said first current.

2. The amplifier according to claim 1, wherein said element is a capacitor having a value substantially equal to said first parasitic capacitive element.

3. The amplifier according to claim 1, wherein said element is a second transistor in diode connection having a control terminal connected to the first input terminal, a first conduction terminal connected to the second output terminal, and a second conduction terminal connected to the control terminal.

4. The amplifier according to claim 3, wherein said second transistor is a bipolar transistor in diode connection which has a base terminal, which corresponds to the control terminal, in common with an emitter terminal, which corresponds to the second conduction terminal, and a collector terminal, which corresponds to the first conduction terminal.

5. The apparatus according to claim 3, wherein said second transistor is a MOS transistor in diode connection which has a gate terminal, which corresponds to the control terminal, in common with a source terminal, which corresponds to the second conduction terminal; and a drain terminal, which corresponds to the first conduction terminal.

6. The amplifier according to claim 3, wherein said second transistor has a total capacitance between its control and first conduction terminals which is substantially equal to said first parasitic capacitive element.

7. The amplifier according to claim 1, wherein said device is a second transistor that in combination with said first transistor forms a differential pair, said second transistor having a second input terminal at which a second input signal, substantially equal to but with a different sign from the said first input signal, is provided.

8. The amplifier according to claim 7, wherein said second transistor comprises a second parasitic capacitive element arranged between the second input and output terminals and through which a third current flows, said amplifier stage comprising another element which is arranged between the input terminal of said second transistor and said first output terminal and which is passed through by a fourth current having a value substantially equal to but of different sign from said third current.

9. The amplifier according to claim 8, wherein said another element is a capacitor having a value substantially equal to said second parasitic capacitive element.

10. The amplifier according to claim 8, wherein said another element is a third transistor in diode connection which has a control terminal connected to the second input terminal, a first conduction terminal connected to the first output terminal, and a second conduction terminal connected to the control terminal.

11. The amplifier according to claim 10, wherein said third transistor has a total capacitance between its control and first conduction terminals which is substantially equal to said second parasitic capacitive element.

12. An amplifier comprising:
a first transistor having a first input terminal, a first output terminal, and a first parasitic capacitive element arranged between the first input and output terminals;
a second transistor that in combination with the first transistor forms a differential pair, the second transistor having a second input terminal and a second output terminal; and
a first capacitive element coupled between the first input terminal and the second output terminal, the first capacitive element having a capacitance that is substantially equal to a capacitance of the first parasitic capacitive element.

13. The amplifier of claim 12, wherein the first capacitive element includes a capacitor having a capacitance substantially equal to the capacitance of the first parasitic capacitive element.

14. The amplifier of claim 12, wherein the first capacitive element includes a diode having a capacitance substantially equal to the capacitance of the first parasitic capacitive element.

15. The amplifier of claim 14, wherein the diode includes a bipolar transistor in diode connection which has a base terminal and an emitter terminal connected in common to the first input terminal, and a collector terminal connected to the second output terminal.

16. The amplifier of claim 14, wherein the diode includes a MOS transistor in diode connection which has a gate terminal and a source terminal connected in common to the first input terminal, and a drain terminal connected to the second output terminal.

17. The amplifier of claim 12, wherein the second transistor includes a second parasitic capacitive element connected between the second input and output terminals, the amplifier further comprising a second capacitive element coupled between the second input terminal and the first output terminal; the second capacitive element having a capacitance that is substantially equal to a capacitance of the second parasitic capacitive element.

18. The amplifier of claim 17, wherein the second capacitive element is a capacitor having a value substantially equal to a capacitance of the second parasitic capacitive element.

19. The amplifier of claim 17, wherein the second capacitive element includes a third transistor in diode connection which has a control terminal connected to the second input terminal, a first conduction terminal connected to the first output terminal, and a second conduction terminal connected to the control terminal.

20. The amplifier of claim 19, wherein the third transistor has a total capacitance between its control and first conduction terminals that is substantially equal to a capacitance of the second parasitic capacitive element.

21. An amplifier comprising:
a first transistor having a control terminal, a first conduction terminal, and a second conduction terminal, wherein a parasitic first current flows between the control terminal and the first conduction terminal;
a second transistor that in combination with the first transistor forms a differential pair, the second transistor having a control terminal, a first conduction terminal, and a second conduction terminal; and
means for providing a second current between the control terminal of the first transistor and the first conduction terminal of the second transistor, the second current having a value equal to but of a different sign from said first current.

22. The amplifier of claim 21, wherein the first transistor includes a parasitic capacitive element between the control and first conduction terminals of the first transistor and the means includes a capacitor having a capacitance substantially equal to a capacitance of the parasitic capacitive element.

23. The amplifier of claim 21, wherein the first transistor includes a parasitic capacitive element between the control and first conduction terminals of the first transistor and the means includes a diode having a capacitance substantially equal to a capacitance of the parasitic capacitive element.

24. The amplifier of claim 23, wherein the diode includes a bipolar transistor in diode connection which has a base terminal and an emitter terminal connected in common to the control terminal of the first transistor, and a collector terminal connected to the first conduction terminal of the second transistor.

25. The amplifier of claim 21, wherein a parasitic third current flows between the control and first conduction terminals of the second transistor, the amplifier further comprising means for providing a fourth current between the control terminal of the second transistor and the first conduction terminal of the first transistor, the fourth current having a value equal to but of a different sign from said third current.

26. The amplifier of claim 25, wherein the second transistor includes a parasitic capacitive element connected between the control and first conduction terminals of the second transistor and the means for proving a fourth current includes a capacitive element coupled between the control terminal of the second transistor and the first conduction terminal of the first transistor, the capacitive element having a capacitance that is substantially equal to a capacitance of the parasitic capacitive element.

27. The amplifier of claim 26, wherein the capacitive element is a capacitor having a value substantially equal to a capacitance of the parasitic capacitive element.

28. The amplifier of claim 26, wherein the capacitive element includes a third transistor in diode connection which has a control terminal connected to the control terminal of the second transistor, a first conduction terminal connected to the first conduction terminal of the first transistor, and a second conduction terminal connected to the control terminal of the third transistor.
